(19) United States
(12) Patent Application Publication
(10) Pub. No.: US 2025/0301841 A1
(43) Pub. Date: Sep. 25, 2025

(54) LIGHT EMITTING DISPLAY DEVICE AND LIGHT EMITTING DISPLAY PANEL

(71) Applicant: LG Display Co., Ltd., Seoul (KR)

(72) Inventors: Sun-Woong HAN, Paju-si (KR); Hyeon-Yeong LEE, Paju-si (KR); Hyun-Gyu SHIN, Paju-si (KR)

(73) Assignee: LG Display Co., Ltd., Seoul (KR)

(21) Appl. No.: 19/071,675

(22) Filed: Mar. 5, 2025

(30) Foreign Application Priority Data
Mar. 22, 2024 (KR) 10-2024-0039608

(51) Int. Cl. H10H 29/37; H10H 29/39; H10H 29/80; H10H 29/85; H10H 29/855

(52) U.S. Cl. CPC H10H 29/37; H10H 29/39; H10H 29/8323; H10H 29/8325; H10H 29/8552; H10H 29/8581

(57) ABSTRACT

Disclosed is a light emitting display device and a light emitting display panel. The light emitting display device includes a first column spacer and a second column spacer disposed on a bank layer. The first column spacer has a different shape form the second column spacer, and at least one of the first column spacer and the second column spacer includes a light-shielding material. The column spacer with the light-shielding material is disposed apart from a reflective electrode of a light emitting diode so that a metal component in the reflective electrode is not reacted with a component with the light-shielding material in the column spacer. Light reflected from metal electrodes and external light is blocked by the column spacer so that the light emitting display device with beneficial luminous efficiency is realized.

### CROSS-REFERENCE TO RELATED APPLICATIONS

This application claims priority under 35 U.S.C. § 119(a) benefit of the Republic of Korea Patent Application No. 10-2024-0039608, filed in the Republic of Korea on Mar. 22, 2024, the entire contents of which are hereby expressly incorporated for all purposes.

### BACKGROUND

### Technical Field

The present disclosure relates to a light emitting display device and a light emitting display panel, and more particularly to, a light emitting display device and a light emitting panel with minimal dead pixels, lower external light reflectivity, and beneficial luminous efficiency.

### Discussion of the Related Art

Flat display devices comprising a light emitting diode (LED) have been investigated as display devices that can replace a liquid crystal display device (LCD). The electrode configurations in the LED can implement unidirectional or bidirectional images. Also, the LED can be formed even on a flexible transparent substrate such as a plastic substrate so that a flexible or a foldable display device can be realized with ease using the LED. In addition, the LED can be driven at a lower voltage and the LED has advantageous high color purity compared to the LCD.

The LED emits light as holes injected from anode and electrons injected from cathode are recombined within an emitting material layer to generate excitons of unstable energy state, and the excitons convert to a stable ground state. A bank layer is disposed in sides of the LED in order to separate each pixel area in the light emitting display device with the LED. The bank layer disposed in a non-emitting area comprises black material so that the bank layer blocks light reflected to the non-emitting area.

The description provided in the description of the related art section should not be assumed to be prior art merely because it is mentioned in or associated with the description of the related art section. The description of the related art section may include information that describes one or more aspects of the subject technology, and the description in this section does not limit the invention.

### SUMMARY

The inventor has realized as the metal electron component of the LED reacts with components of the bank layer with the black material, a part of the metal electrode of the LED can be removed. As the thickness of the metal electrode is not evenly disposed, dead pixels are occurred in the pixel area. In addition, there is a need to develop a light emitting display device with beneficial luminous efficiency and visibility.

Accordingly, embodiments of the present disclosure are directed to a light emitting display device and a light emitting display panel that substantially obviate one or more of the problems due to limitations and disadvantages of the related art.

An aspect of the present disclosure is to provide a light emitting display device with minimal or no dead pixels by suppressing a reaction between a meal electrode component in a light emitting diode, and a component in a bank layer.

Another aspect of the present disclosure is to provide a light emitting display device with beneficial luminous or light efficiency by minimizing reflective light from electrodes and/or lines.

Additional features and aspects will be set forth in the description that follows, and in part will be apparent from the description, or can be learned by practice of the inventive concepts provided herein. Other features and aspects of the inventive concept may be realized and attained by the structure particularly pointed out in the written description, or derivable therefrom, and the claims hereof as well as the appended drawings.

To achieve these and other aspects of the inventive concepts, as embodied and broadly described, in one aspect, a light emitting display device comprises a substrate defining an emitting area and a non-emitting area surrounding the emitting area; a thin film transistor disposed in the non-emitting area on the substrate; a light emitting diode including a first electrode connected to a drain electrode of the thin film transistor and disposing in the emitting area; a bank layer surrounding the first electrode at each pixel region and disposed in the non-emitting area; and a column spacer disposed on the bank layer, the column spacer including a first column spacer and a second column spacer disposed sequentially on the bank layer, wherein the first column spacer has a different shape from the second column spacer, and wherein the at least one of the first column spacer and the second column spacer comprises a light-shielding material.

As an example, one of the first column spacer and the second column spacer can have a cross-sectional shape of which width gradually increases toward the bank layer, and the other of the first column spacer and the second column spacer can have a cross-sectional shape of which width gradually decreases toward the bank layer.

In one exemplary embodiment, the first column spacer can have a cross-sectional shape of which width gradually increases toward the bank layer and the second column spacer can have a cross-sectional shape of which width gradually decreases toward the bank layer.

Both the first column spacer and the second column spacer can have the light-shielding material.

As an example, the light-shielding material can be selected from a black colorant of one of a black pigment and a black dye, carbon black, a carbon nanotube, graphene, and combinations thereof.

In another exemplary embodiment, the light emitting display device can further comprise a passivation layer covering the thin film transistor, and the passivation layer can comprise a light-shielding material.

As an example, the bank layer can comprise a white bank layer or a gray bank layer.

For example, the white bank layer comprises white heat dissipating particles, and the gray bank layer comprises white heat dissipating particles and a light-shielding material.

For example, weight ratio between the white heat dissipating particles and the light-shielding material is 2:8 to 8:2.

In one exemplary embodiment, the bank layer can comprise heat dissipating particles.

For example, the heat dissipating particles comprises white heat dissipating particles.

For example, the heat dissipating particles comprises boron nitride BN.

For example, the heat dissipating particles can be selected from metal material, carbon-containing material, inorganic oxide, inorganic nitride, inorganic arsenide, inorganic carbide, and combinations thereof.

The metal material can be selected from aluminum (Al), gold (Au), copper (Cu), silver (Ag), and combinations thereof.

The carbon-containing material can be selected from graphite, graphene, a carbon nanotube (CNT), and combinations thereof.

The inorganic oxide can be selected from aluminum oxide (Al₂O₃), silica (SiO₂), magnesium oxide (MgO), zinc oxide (ZnO), zirconium oxide (ZrO₂), and combinations thereof, the inorganic nitride can be selected from aluminum nitride (AlN), boron nitride (BN), and combinations thereof, and/or the inorganic arsenide can be boron arsenide (BAs).

In one exemplary embodiment, the first electrode can comprises a reflective electrode layer; and a transparent conductive layer disposed on a top surface of the reflective electrode layer or a bottom surface of the reflective electrode layer.

For example, the bank layer comprises a white bank layer or a gray bank layer.

For example, the reflective electrode layer can comprise silver (Au) or aluminum-palladium-copper (APC) alloy.

The light emitting diode can further comprise an emissive layer disposed on the first electrode; and a second electrode disposed on the emissive layer, the column spacer and the bank layer.

In one exemplary embodiment, the first column spacer and the second column spacer can have a refractive index smaller than a refractive index of the second electrode.

In another exemplary embodiment, the first electrode can comprise a transparent conductive layer with a transparent conductive oxide, and the bank layer can comprise a light-shielding material.

As an example, the light emitting diode can comprise an organic light emitting diode, a quantum dot light emitting diode, a micro light emitting diode and a nano light emitting diode.

In another aspect, a light emitting display panel, having an emitting area and a non-emitting area surrounding the emitting area, comprises a thin film transistor disposed in the non-emitting area; a light emitting diode including a first electrode connected to a drain electrode of the thin film transistor and disposing in the emitting area; a bank layer surrounding the first electrode at each pixel region and disposed in the non-emitting area; and a column spacer disposed on the bank layer, the column spacer including a first column spacer and a second column spacer disposed sequentially on the bank layer, wherein the first column spacer has a different shape from the second column spacer, and wherein the at least one of the first column spacer and the second column spacer comprises a light-shielding material.

For example, one of the first column spacer and the second column spacer has a cross-sectional shape of which width gradually increases toward the bank layer, and the other of the first column spacer and the second column spacer has a cross-sectional shape of which width gradually decreases toward the bank layer.

For example, the bank layer comprises a white bank layer or a gray bank layer.

For example, the white bank layer comprises white heat dissipating particles, and the gray bank layer comprises white heat dissipating particles and a light-shielding material.

One or more exemplary embodiments, the bank layer contacted to the first electrode in the light emitting diode does not comprise the light-shielding material and at least one column spacer disposed on the bank layer comprises the light-shielding material. The metal component of the first electrode in the light emitting diode is not reacted with the component in the non-black bank layer.

As the metal component of the first electrode does not react with the component in the bank layer, it is possible to prevent a part of the first electrode from removing, and therefore, to prevent or minimize the dead pixels in the pixel area caused by the washout of the first electrode.

The first column spacer and the second column spacer with different shape are disposed sequentially on the bank layer, and at least one of the first column spacer and the second column spacer comprises the light-shielding material. The light reflected from the reflective electrode of the light emitting diode and/or the metal electrodes and metal lines of the thin film transistor and/or external light can be blocked efficiently by the column spacer with the light-shielding material.

Optionally, the passivation layer disposed between the thin film transistor and the light emitting diode can comprise the light-shielding material. Accordingly, it is possible to minimize the external light and/or the reflective light entering the thin film transistor.

Therefore, it is possible to prevent or reduce the visibility from lowering caused by the reflective light and/or the external light, and to maximize luminous efficiency. The light emitting display device with beneficial luminous property can be realized.

It is to be understood that both the foregoing general description and the following detailed description are exemplary and explanatory, and are intended to provide further explanation of the inventive concepts as claimed.

### BRIEF DESCRIPTION OF THE DRAWINGS

The accompanying drawings, which provide a further understanding of the disclosure and are incorporated in and constitute a part of this application, illustrate embodiments of the disclosure and together with the description serve to explain principles of the disclosure.

FIG. 1 illustrates a schematic circuit diagram of a light emitting display device in accordance with one or more exemplary embodiments of the present disclosure.

FIG. 2 illustrates a cross-sectional view of a light emitting display device in accordance with an exemplary embodiment of the present disclosure.

FIG. 3 illustrates a cross-sectional view of a light emitting diode in accordance with an exemplary embodiment of the present disclosure.

FIG. 4 is a schematic view illustrating that light reflected from the metal electrode and reflective electrode is blocked by a column spacer with a light-shielding material in a light emitting display device in accordance with an exemplary embodiment of the present disclosure.

FIG. 5 is a schematic view illustrating a reaction between a composition with black colorant for a bank layer and silver of the reflective electrode in a conventional light emitting display device.

FIG. 6 illustrates dead pixel in a pixel area by the reaction between the composition with black colorant for a bank layer and silver of the reflective electrode in a conventional light emitting display device.

FIG. 7 illustrates a cross-sectional view of a light emitting display device in accordance with another exemplary embodiment of the present disclosure.

FIG. 8 is a schematic view illustrating that light reflected from the metal electrode and reflective electrode is blocked by a column spacer with a light-shielding material in a light emitting display device in accordance with another exemplary embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure and methods for achieving the same will become apparent from the descriptions of various examples herein below with reference to the accompanying drawings. However, the present disclosure is not limited to the various examples disclosed herein but may be implemented in various different forms. The examples of the present disclosure are provided to make the description of the present disclosure thorough and to fully convey the scope of the present disclosure to those skilled in the art. It is to be noted that the examples of the present disclosure are defined only by the claims.

The shape, size, ratio, angle, number, and the like shown in the drawings to illustrate various exemplary embodiments of the present disclosure are merely provided for illustration, and the disclosure is not limited to the content shown in the drawings. Wherever possible, the same reference numbers will be used throughout the drawings to refer to the same or like parts. In the following description, detailed descriptions of technologies or configurations related to the present disclosure may be omitted so as to avoid unnecessarily obscuring the subject matter of the present disclosure.

When terms such as “include,” “have,” “comprise,” “contain,” “constitute,” “make up of,” “formed of,” and “consist of” are used throughout the disclosure, an additional component may be present, unless “only” is used. A component described in a singular form encompasses a plurality thereof unless particularly stated otherwise.

The shapes, sizes, dimensions (e.g., length, width, height, thickness, radius, diameter, area, etc.), ratios, angles, numbers of elements, and the like illustrated in the accompanying drawings for describing the exemplary embodiments of the present disclosure are merely examples, and the present disclosure is not limited thereto. Like reference numerals generally denote like elements throughout the specification.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The components included in the exemplary embodiments of the present disclosure should be interpreted to include an error range, even if there is no additional particular description thereof.

In describing the variety of exemplary embodiments of the present disclosure, when terms describing positional relationships such as “on”, “above”, “over”, “below”, “under”, “beside”, “beneath”, “near”, “close to,” “adjacent to”, “on a side of”, “next” are used, at least one intervening element may be present between the two elements, unless “immediately” or “directly” is also used.

Spatially relative terms, such as “under,” “below,” “beneath”, “lower,” “over,” “upper” and the like, may be used herein for ease of description to describe one element or feature's relationship to another element(s) or feature(s) as illustrated in the figures. It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the exemplary term “below” can encompass both an orientation of below and above. Similarly, the exemplary term “above” or “over” can encompass both an orientation of “above” and “below”.

When an element or layer is disposed “on” another element or layer, another layer or another element may be interposed directly on the other element or therebetween.

In describing the variety of exemplary embodiments of the present disclosure, when terms related to temporal relationships, such as “after”, “subsequently”, “next”, and “before”, are used, the non-continuous case may be included, unless “immediately” or “directly” is also used.

In describing the variety of exemplary embodiments of the present disclosure, terms such as “first”, “second”, “A”, “B”, “(A)”, or “(B)” may be used to describe a variety of components, but these terms only aim to distinguish the same or similar components from one another. Accordingly, throughout the disclosure, a “first” component may be the same as a “second” component within the technical concept of the present disclosure, unless specifically mentioned otherwise.

The term “at least one” should be understood to include all possible combinations from one or more related items. For example, “at least one of a first item, a second item, or a third item” means each of the first, second, and third items, as well as all combinations of two or more of the first, second, and third items.

A term “device” used herein may refer to a display device including a display panel and a driver for driving the display panel. Examples of the display device may include a light emitting element, and the like. In addition, examples of the device may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto.

Respective features of various examples of the present disclosure may be partially or entirely coupled to or combined with each other, and may be technically variously interconnected or operated, and the respective examples may be implemented independently of each other or implemented together in associative relations.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In the aspects of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

In giving reference numerals to components in the respective drawings, identical components may have the same reference numerals as much as possible even if they are shown in different drawings. In addition, the scale of the components shown in the attached drawings may be different from an actual scale for convenience of explanation, and thus the present disclosure is not limited to the scale shown in the drawings.

Reference will now be made in detail to aspects of the disclosure, examples of which are illustrated in the accompanying drawings. Wherever possible, the same reference numbers will be used throughout the drawings to refer to the same or like parts.

All the components of each light emitting display device according to all exemplary embodiments of the present disclosure are operatively coupled and configured.

The present disclosure relates to a light emitting display device that comprises plural column spacers disposed on a bank layer located in a non-emitting area, and that at least one column spacer among the plural column spacers comprises a light-shielding material. The light emitting display device will be described in more detail below.

### First Example

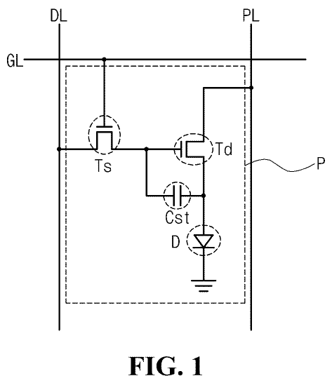

FIG. 1 illustrates a schematic circuit diagram of a light emitting display device in accordance with one or more exemplary embodiments of the present disclosure.

As illustrated in FIG. 1, a gate line GL, a data line DL and power line PL, each of which crosses each other to define a pixel region P, are provided in a light emitting display device. Thin film transistors TFTs such as a switching thin film transistor Ts and a driving thin film transistor Td, a storage capacitor Cst and a light emitting diode D are disposed within the pixel region P.

Active layers of the thin-film transistors TFTs may be formed of a semiconductor material, such as an oxide semiconductor, amorphous semiconductor, or polycrystalline semiconductor, but is not limited thereto.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be made of polycrystalline silicon (poly-Si), but is not limited thereto.

The amorphous semiconductor material may be made of amorphous silicon (a-Si), but is not limited thereto.

The pixel region P can comprise a first pixel region, a second pixel region and a third pixel region, and optionally a fourth pixel region. As an example, the first pixel region can be a red (R) pixel region, the second pixel region can be a green (G) pixel region, the third pixel region can be a blue (B) pixel region, and the fourth pixel region can be a white (W) pixel region. However, exemplary embodiments of the present disclosure are not limited to such examples. The light emitting display device can comprise a plurality of such pixel regions P which can be arranged in a matrix configuration or other configurations.

The switching thin film transistor Ts is connected to the gate line GL and the data line DL. The driving thin film transistor Td and the storage capacitor Cst are connected between the switching thin film transistor Ts and the power line PL. The light emitting diode D is connected to the driving thin film transistor Td. When the switching thin film transistor Ts is turned on by a gate signal applied to the gate line GL, a data signal applied to the data line DL is applied to a gate electrode of the driving thin film transistor Td and one electrode of the storage capacitor Cst through the switching thin film transistor Ts.

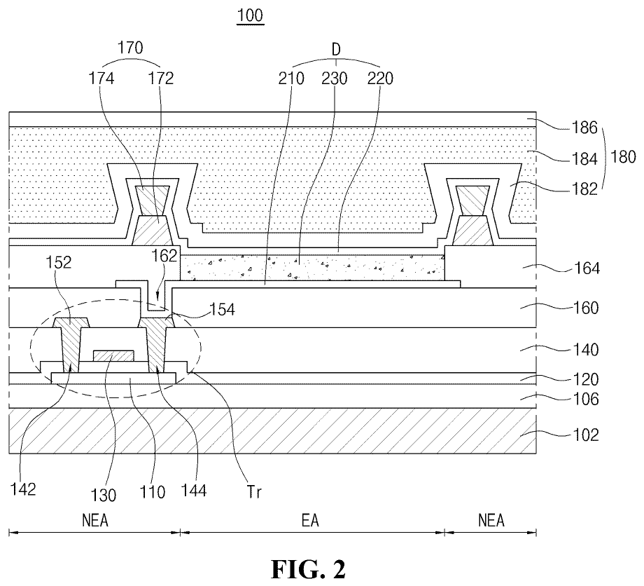

The driving thin film transistor Td is turned on by the data signal applied to a gate electrode 130 (FIG. 2) so that a current proportional to the data signal is supplied from the power line PL to the light emitting diode D through the driving thin film transistor Td. And then, the light emitting diode D emits light having a luminance proportional to the current flowing through the driving thin film transistor Td. In this case, the storage capacitor Cst is charged with a voltage proportional to the data signal so that the voltage of the gate electrode in the driving thin film transistor Td is kept constant during one frame. Therefore, the light emitting display device can display a desired image.

The light emitting display device 100 can further comprise plural pad portions and a driver. For example, the driver can comprise a gate driver that can be disposed as gate in panel (GIP) and comprising a driving signal portion proving a gate driving signal to a thin film transistor Tr (FIG. 2), and a data driver proving a data signal to the thin film transistor Tr.

As an example, the data driver can be connected to the pad portion disposed in a non-emitting area NEA on a substrate 102 (FIG. 2) through a circuit film such as a flexible printed circuit board (FPCB) mounted on a separated printed circuit board (PCB). In another exemplary embodiment, the data driver can be disposed on a circuit film by chip-on-film (COF), chip-on-glass (COG), chip-on-plastic (COP) and/or tape-carrier-package (TCP) to connect to the pad portion on the substrate 102 (FIG. 2).

FIG. 2 illustrates a cross-sectional view of a light emitting display device in accordance with an exemplary embodiment of the present disclosure. The pixel circuit configuration of FIG. 1 can be used in the display device of FIG. 2 or other figures of the present disclosure.

As illustrated in FIG. 2, the light emitting display device 100 comprises a substrate 102, a thin film transistor Tr disposed on the substrate 102, and a light emitting diode D connected to the thin film transistor Tr.

The substrate 102 defines an emitting area (display area) EA, and a non-emitting area (non-display area) NEA surrounding the emitting area EA. As an example, the substrate 102 defines a red (R) pixel region, a green (G) pixel region and a blue (B) pixel region, and the light emitting diode D can be disposed in each pixel region P. In other words, the light emitting diode D emitting red light, green light and blue light can be disposed in the red (R) pixel region, the green (G) pixel region and the blue (B) pixel region, respectively. The substrate 102 onto which the thin film transistor Tr and the light emitting diode D are dispose forms an array substrate.

Each of the plurality of subpixels SP is a minimum unit which configures the emitting area (display area) EA and n subpixels SP disposed in n pixel regions respectively form one pixel. Each of the plurality of subpixels SP may emit light having different wavelengths from each other. The plurality of subpixels may include first to third subpixels which emit different color light from each other. Each pixel P may be divided into a red subpixel, a green subpixel, and a blue subpixel, for color rendering. Each pixel P may further include a white subpixel. The plurality of subpixels SP may be variously modified in colors and configurations, as necessary. However, the present disclosure is not limited thereto.

For example, the plurality of subpixels SP may include red, green, and blue subpixels, in which the red, green, and blue subpixels may be disposed in a repeated manner. Alternatively, the plurality of subpixels SP may include red, green, blue, and white subpixels, in which the red, green, blue, and white subpixels may be disposed in a repeated manner, or the red, green, blue, and white subpixels may be disposed in a quad type. For example, the red sub pixel, the blue sub pixel, and the green sub pixel may be sequentially disposed along a row direction, or the red sub pixel, the blue sub pixel, the green sub pixel and the white sub pixel may be sequentially disposed along the row direction. However, in the embodiment of the present disclosure, the color type, disposition type, and disposition order of the subpixels are not limiting, and may be configured in various forms according to light-emitting characteristics, device lifespans, and device specifications.

Meanwhile, the subpixels may have different light-emitting areas according to light-emitting characteristics. For example, a subpixel that emits light of a color different from that of a blue subpixel may have a different light-emitting area from that of the blue subpixel. For example, the red subpixel, the blue subpixel, and the green subpixel, or the red subpixel, the blue subpixel, the white subpixel, and the green subpixel may each has a different light-emitting area.

In one exemplary embodiment, the substrate 102 can be a flexible substrate. As an example, the substrate 102 can have a film structure that comprises a polyester-containing polymer, a silicone-containing polymer, an acryl-containing polymer, a polyolefin-containing polymer, co-polymers thereof and/or combinations thereof. For example, the substrate 102 can be a thin plastic film that can be selected from, but is not limited to, polyethylenenaphthalate (PEN), polyethylene terephthalate (PET), polybutylene terephthalate (PBT), polysilane, polysiloxane, polysilazane, polycarbosilane, polyacrylate, polymethacrylate, polymethylacrylate, polymethylmethacrylate (PMMA), polyethylacrylate, polyethylmethacrylate, cyclic olefin copolymer (COC), cyclic olefin polymer (COP), polyethylene (PE), polypropylene (PP), polyimide (PI), polystyrene (PS), polyacetal, polyetherethersulfone (PEES), polyethersulfone (PES), polytetrafluoroethylene (PTFE), polyvinylchloride (PVC), polycarbonate (PC), polyvinylidenechloride (PVDF), perfluoroalkyl polymers (PFA), styrene acrylic nitrile copolymers (SAN), combinations thereof and/or copolymers thereof. Alternatively, the substrate 102 can be a glass substrate.

A buffer layer 106 can be disposed on the substrate 102, and the thin film transistor Tr can be disposed on the buffer layer 106. As an example, the buffer layer 106 can be a buffer layer that laminates sequentially plural thin films.

As an example, the buffer layer 106 can be alternately laminated with silicon nitride (SiNₓ) and silicon oxide (SiOₓ) (0<X≤2). For example, the first buffer layer 106 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto. Alternatively, the buffer layer 106 can be disposed by repeatedly laminating organic and inorganic layers alternately. The buffer layer 106 can act as an encapsulation layer to prevent or reduce external moisture and the likes from penetrating to the substrate 102. In some exemplary embodiment, the buffer layer 106 can be omitted.

A semiconductor layer (active layer) 110 is disposed on the buffer layer 106. In one exemplary embodiment, the semiconductor layer 110 can comprise, but is not limited to, oxide semiconductor materials. For example, the oxide semiconductor material can comprise, but is not limited to, indium-gallium-zinc-oxide (IGZO), indium-zinc-oxide (IZ), zinc-tin-oxide (ZTO), zinc-oxide (ZnO), and combinations thereof. In one exemplary embodiment, the semiconductor layer 110 comprising the oxide semiconductor material can have a single-layered structure or a multiple-layered structure each of which comprises different oxide semiconductor material.

When the semiconductor layer 110 comprises the oxide semiconductor material, a light-shield pattern can be disposed under the semiconductor layer 110, and the light-shield pattern can prevent light from being incident toward the semiconductor layer 110, thereby, preventing or reducing the semiconductor layer 110 from being degraded by the light.

Alternatively, the semiconductor layer 110 can comprise polycrystalline silicon. As an example, the semiconductor layer 110 can comprise LTPS (low temperature poly-silicon). The polysilicon material has high mobility, low energy power consumption and beneficial credibility. In this case, the semiconductor layer 110 can comprise a channel area forming a channel in driving, a source area and a drain area at both sides of the channel areal. The channel area, the source area and the drain area can be defined by ion doping (impurity doping).

A gate insulating layer 120 comprising an insulating material is disposed on the semiconductor layer 110 on an entire surface of the substrate 102. The gate insulating layer 120 can comprise, but is not limited to, an inorganic insulating material such as silicon oxide (SiOₓ, wherein 0<x≤2) or silicon nitride (SiNₓ, wherein 0<x≤2).

A gate electrode 130 made of a conductive material such as a metal is disposed on the gate insulating layer 120 so as to correspond to a center, the channel area, of the semiconductor layer 110. While the gate insulating layer 120 is disposed on the entire area of the substrate 102 as shown in FIG. 2, the gate insulating layer 120 can be patterned identically as the gate electrode 130.

In one exemplary embodiment, the gate electrode 130, the gate line GL (FIG. 1) and the data line DL (FIG. 1) can be made of the same material. As an example, each of the gate electrode 130, the gate line GL and the data line DL can independently comprise, but is not limited to, low-resistant metal such as aluminum (Al), aluminum alloy (e.g., AlNd), copper (Cu), copper alloy, molybdenum (Mo), molybdenum titanium alloy (MoTi), chrome (Cr), titanium (Ti), or any combination thereof. Each of the gate electrode 130, the gate line GL and the data line DL can have a single-layered structure or a multiple-layered structure such as a dual-layered structure and/or a triple-layered structure, but not limited thereto.

An interlayer insulating layer 140 comprising an insulating material is disposed on the gate electrode 130 and the gate line GL (FIG. 1) and covers an entire surface of the substrate 102. The interlayer insulating layer 140 can comprise, but is not limited to, an inorganic insulating material such as silicon oxide (SiOₓ, wherein 0<x≤2) or silicon nitride (SiNₓ, wherein 0<x≤2), or an organic insulating material such as benzocyclobutene or photo-acryl. For example, the interlayer insulating layer 140 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

In one exemplary embodiment, a second interlayer insulating layer can be disposed on the interlayer insulating layer 140. The second interlayer insulating layer can comprise, but is not limited to, an inorganic insulating material such as silicon oxide (SiOₓ, wherein 0<x≤2) or silicon nitride (SiNₓ, wherein 0<x≤2). For example, the second interlayer insulating layer may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

The interlayer insulating layer 140 has first and second semiconductor layer contact holes 142 and 144 that expose or do not cover two sides of top surface, i.e., the source area and the drain area, of the semiconductor layer 110. The first and second semiconductor layer contact holes 142 and 144 are disposed on opposite sides of the gate electrode 130 and spaced apart from the gate electrode 130.

In one exemplary embodiment, the first and second semiconductor layer contact holes 142 and 144 are formed within the gate insulating layer 120 and the interlayer insulating layer 140 as shown in FIG. 2. Alternatively, in certain exemplary embodiments, the first and second semiconductor layer contact holes 142 and 144 can be formed only within the interlayer insulating layer 140 when the gate insulating layer 120 is patterned identically as the gate electrode 130, but not limited thereto.

A source electrode 152 and a drain electrode 154, each of which is made of conductive material such as a metal, are disposed on the interlayer insulating layer 140. The source electrode 152 and the drain electrode 154 are spaced apart from each other on opposing sides of the gate electrode 130, and contact both sides, the source area and the drain area, of the semiconductor layer 110 through the first and second semiconductor layer contact holes 142 and 144, respectively.

As an example, each of the source electrode 152 and the drain electrode 154 can comprise, but is not limited to, low-resistant metal such as Al, aluminum alloy (e.g., AlNd), Cu, copper alloy, Mo, MoTi, Cr, Ti, or any combination thereof.

The semiconductor layer 110, the gate electrode 130, the source electrode 152 and the drain electrode 154 constitute the thin film transistor Tr, which acts as a driving element. The thin film transistor Tr in FIG. 2 has a coplanar structure in which the gate electrode 130, the source electrode 152 and the drain electrode 154 are disposed on the semiconductor layer 110. Alternatively, the thin film transistor Tr can have an inverted staggered structure in which a gate electrode is disposed under a semiconductor layer and a source and drain electrodes are disposed on the semiconductor layer. In this case, the semiconductor layer can comprise amorphous silicon. However, the present disclosure is not limited thereto.

The gate line GL (FIG. 1) and the data line DL (FIG. 1) crosses each other to define the pixel region P, and the switching thin film transistor Ts (FIG. 1) is connected to the gate line GL and the data line DL. For example, the plurality of data lines DL and the plurality of gate lines GL may cross each other. Each of the plurality of data lines DL may be disposed to extend in the column direction. Each of the plurality of gate lines GL may be disposed to extend in the row direction. According to exemplary embodiments of the disclosure, the column direction and the row direction may be relative directions. In other words, the column direction may be the row direction depending on the viewpoint, and the row direction may be the column direction depending on the viewpoint. For convenience of description, described below is an example in which each of the plurality of data lines DL is disposed in the column direction, and each of the plurality of gate lines GL is disposed in the row direction, but exemplary embodiments of the disclosure are not limited thereto. For example, each of the plurality of data lines DL may be disposed in the row direction, and each of the plurality of gate lines GL may be disposed in the column direction. In exemplary embodiments of the disclosure, the angle between the row direction and the column direction may be 90 degrees or may an angle different from 90 degrees. Further, in exemplary embodiments of the disclosure, the row direction may be referred to as a first direction, and the column direction may be referred to as a second direction. Alternatively, the column direction may be referred to as a first direction, and the row direction may be referred to as a second direction.

The switching thin film transistor Ts is connected to the thin film transistor Tr as the driving element. The power line PL (FIG. 1) is disposed parallel to the data line DL, and the storage capacitor Cst is disposed so that the voltage of the gate electrode 130 in the thin film transistor Tr as the driving element can be kept constant during one frame.

A passivation layer 160 is disposed on the source and drain electrodes 152 and 154. The passivation layer 160 covers the thin film transistor Tr on the entire substrate 102. The passivation layer 160 has a flat top surface and a drain contact hole (or a contact hole) 162 that exposes or does not cover the drain electrode 154 of the thin film transistor Tr. In FIG. 2, the drain contact hole 162 is disposed on the second semiconductor contact hole 144, but the drain contact hole 162 can be disposed apart from the second semiconductor contact hole 144.

In one exemplary embodiment, the passivation layer 160 can comprise the same material as the gate insulating layer 120 and/or the interlayer insulating layers 140. In another exemplary embodiment, the passivation layer 160 can comprise an organic material for planarization of the substrate 102. However, the present disclosure is not limited thereto.

For example, the passivation layer 160 can comprise, but is not limited to, acryl-containing resins, epoxy-containing resins, phenol-containing resins, polyamide-containing resins, polyimide-containing resins, unsaturated polyester resins, poly-phenylene-ether resins poly-phenylene-sulfide resins, benzocyclobutene and combination thereof.

Alternatively, the passivation layer 160 can comprise inorganic material such as, but is not limited to, silicon oxides, aluminum oxides, titanium oxides, silicon nitrides, aluminum nitrides, zirconium nitrides, titanium nitrides, hafnium nitrides, tantalum nitrides, and the likes. The passivation layer 160 can have a single-layered structure or multiple-layered structure. For example, the passivation layer 160 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

Alternatively, another passivation layer can be disposed between the source electrode 152, the drain electrode 154 and the interlayer insulating layer 140, and the passivation layer 160. In one exemplary embodiment, another passivation layer can comprise an inorganic insulating material such as silicon oxide (SiOₓ, wherein 0<x≤2) or silicon nitride (SiNₓ, wherein 0<x≤2), and have a single-layered structure or a multiple-layered structure. For example, the another passivation layer may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto. In another exemplary embodiment, another passivation layer can comprise an organic material such as acryl-containing resins, epoxy-containing resins, phenol-containing resins, polyamide-containing resins and/or polyimide-containing resins.

A light emitting diode (LED) D is disposed on the passivation layer 160. In one exemplary embodiment, the light emitting diode D can comprise, but is not limited to, an organic light emitting diode (OLED), a quantum dot light emitting diode (QLED), a micro light emitting diode and a nano light emitting diode.

As an example, the light emitting diode D can comprise a first electrode 210 that is disposed on the passivation layer 160 and connected to the drain electrode 154 of the thin film transistor Tr. The light emitting diode D can further comprise an emissive layer 230 and a second electrode 220 each of which is disposed sequentially on the first electrode 210.

One of the first electrode 210 and the second electrode 220 can be an anode, and the other of the first electrode 210 and the second electrode 220 can be a cathode. One of the first electrode 210 and the second electrode 220 can be a reflective electrode, and the other of the first electrode 210 and the second electrode 220 can be a transmissive electrode.

The first electrode 210 is disposed separately in each pixel region P. In one exemplary embodiment, the first electrode 210 can be an anode and comprise conductive material having relatively high work function value. For example, the first electrode 210 can comprise a transparent conductive oxide (TCO).

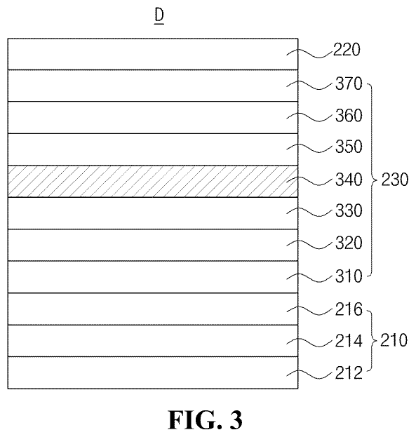

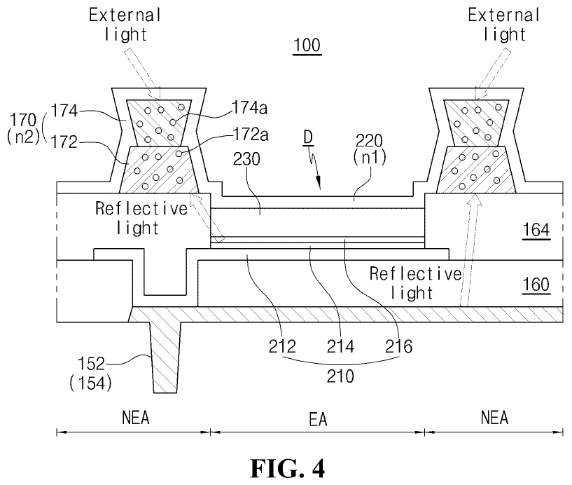

In one exemplary embodiment, when the light emitting display device 100 is a bottom-emission type, the first electrode 210 can have a single-layered structure of the TCO. Alternatively, when the light emitting display device 100 is a top-emission type, the first electrode 210 can comprise one or more transparent conductive layers 212 and 216 (FIGS. 3 and 4) and a reflective electrode layer 214 (FIGS. 3 and 4) disposed on or under the one or more transparent conductive layers 212 and 216.

In addition, a bank layer 164 is disposed on the first passivation layer 160 in order to cover edges of the first electrode 210. The bank layer 164 may be disposed at a boundary between the plurality of subpixels SP and suppress a color mixture of light beams from the plurality of subpixels SP. The bank layer 164 can cover the edge of first electrode 210 and can be formed to expose a portion of first electrode 210. Accordingly, bank layer 164 can prevent a current from being concentrated at an end of first electrode 210 so that it is possible to prevent or reduce a deterioration of light emitting efficiency. For example, the bank layer 164 exposes or does not cover a center of the first electrode 210 corresponding to each pixel region P. The opening of the bank layer 164 may expose a portion of the first electrode 210 to form the emission area. For example, the opening of the bank layer 164 may overlap a portion of the first electrode 210. In other words, the first electrode 210 can have a structure that is separated for each pixel region P with the bank layer 164 as the boundary for each pixel region P. The bank layer 164 may be formed of a material including a black pigment, or an organic material such as a benzocyclobutene resin, a polyimide resin, an acrylic resin, or a photosensitive polymer, but exemplary embodiments of the disclosure are not limited thereto. When the bank layer 164 is formed of a material including a black pigment, a black dye, or the like, it may be a black bank layer. When the bank layer 164 is formed of a material including a black pigment or a black dye, light from the outside may be blocked or light reflected from the outside may be blocked, and thus the luminance of the display device may be further enhanced.

A column spacer 170 is disposed on the bank layer 164. The column spacer 170 is disposed to surround the emission area EA where the light emitting diode D is disposed in each pixel region P, and thus, the column spacer 170 protects the emissive layer 230 from an external pressure. The column spacer 170 can be made of a composition with colorants and can be made of black column spacer with high light absorption rate to absorb reflective light and/or external light, as described below.

The column spacer 170 can comprise a first column spacer 172 and a second column spacer 172 that are disposed sequentially on the bank layer 164 and are different cross-sectional shapes. In one exemplary embodiment, one of the first column spacer 172 and the second column spacer 174 can have a cross-sectional shape (trapezoidal cross-sectional shape) of which width gradually increases toward the bank layer 164, and the other of the first column spacer 172 and the second column spacer 174 can have a cross-section shape (reverse-trapezoidal cross-sectional shape) of which width gradually decreases toward the bank layer 164.

As an example, the first column spacer (Angle spacer) 172 disposed on the bank layer 164 can have a cross-sectional shape of which width gradually increases toward the bank layer 164, and the second column spacer (Reverse Angle spacer) 174 can have a cross-sectional shape of which width gradually decreases toward the bank layer 164. As the second column spacer 174 has the cross-sectional shape of which width gradually decreases toward the bank layer 164, a contact area between the second electrode 220 disposed on the second column spacer 174 and an encapsulation film 180 can be increased.

Accordingly, adhesion performances between the column spacer 170 and the second electrode 220, and the second electrode 220 and the encapsulation film 180 can be improved. In addition, as the second column spacer 174 having the cross-sectional shape of which width gradually decreases toward the bank layer 164, bending stress to the emissive layer 230 in folding the light emitting diode D can be alleviated.

As plural column spacers of the first column spacer 172 and the second column spacer 174 with different cross-sectional shapes are disposed on the bank layer 164, the separation distance between the light emitting diode D and the bank layer 164, and the encapsulation film 180 can be increased. Accordingly, the empty space between the light emitting diode D and the encapsulation film 180 is buffered so that damage to the light emitting diode D from external impact can be minimized.

For example, the first column spacer 172 and the second column spacer 174 can be disposed sequentially on the bank layer 164 with negative photoresist process using half-tone mask, but is not limited thereto. In one exemplary embodiment, each of the first column spacer 172 and the second column spacer 174 can have a thickness of, but is not limited to, about 0.5 um to about 3.0 um, for example, about 1.0 um to about 2.5 um.

An emissive layer 230 is disposed on the first electrode 210. In one exemplary embodiment, the emissive layer 230 can have a single-layered structure of an emitting material layer (EML). In one exemplary embodiment, the EML can comprise organic emitting materials such as host and/or dopant. In another exemplary embodiment, the EML can comprise inorganic luminescent particles such as quantum dots (QDs) and quantum rods (QRs). For example, the organic dopant can comprise phosphorescent material, fluorescent material and/or delayed fluorescent material emitting red (R) color, green (G) color and blue (B) color. The LED D can emit red (R) color, green (G) color, blue color (B) and/or white (W) color. However, the present disclosure is not limited thereto.

In another exemplary embodiment, the emissive layer 230 can have a multiple-layered structure. For example, the emissive layer 230 can further comprise a hole injection layer (HIL), a hole transport layer (HTL) and/or an electron blocking layer (EBL) disposed sequentially between the first electrode 210 and the EML, and/or a hole blocking layer (HBL), an electron transport layer (ETL), an electron injection layer (EIL) and/or a charge generation layer (CGL) disposed between the EML and the second electrode 210 (FIG. 3). Two or more emitting parts of the emissive layer 230 can form a tandem structure (FIG. 3), or the emissive layer 230 can consist of a single emitting part.

The second electrode 220 is disposed on the substrate 102 above which the emissive layer 230 is disposed. The second electrode 220 can be disposed on the emissive layer 230, the bank layer 164 and the column spacer 170. The second electrode 220 can be disposed in the entire display area. For example, the emissive layer 230 and the bank layer 164 are disposed over the substrate 102, the column spacer 170 are disposed on the bank layer 164., and the second electrode 220 is disposed to cover the emissive layer 230, the bank layer 164 and the column spacer 170 in the entire display area, but not limited thereto. The second electrode 220 can comprise a conductive material with a relatively low work function value compared to the first electrode 210. When the light emitting display device 100 is a top-emission type, the second electrode 220 is thin so as to have light-transmissive (semi-transmissive) property.

In addition, an adhesive layer can be disposed on the light emitting diode D in order to prevent or reduce outer moisture from penetrating into the light emitting diode D. The adhesive layer can comprise, but is not limited to, an optically clear adhesive (OCA) and a pressure sensitive adhesive (PSA).

An encapsulation film 180 can be disposed on the thin film transistor Tr and the light emitting diode D. The encapsulation film 180 may prevent moisture or oxygen from penetrating into the light emitting element. For example, the encapsulation film 180 may prevent moisture or oxygen from penetrating into the organic material included in an intermediate layer of the light emitting element. The encapsulation film 180 may be formed of a single layer or multiple layers, but exemplary embodiments of the disclosure are not limited thereto. For example, the encapsulation film 180 can have, but is not limited to, a lamination structure of a first inorganic insulating layer 182, an organic insulating layer 184 and a second inorganic insulating layer 186. In certain exemplary embodiments, the encapsulation layer 180 can be omitted.

The first inorganic insulating layer 182 and the second inorganic insulating layer 186 may be formed of an inorganic insulating material enabling low-temperature deposition thereof, such as silicon nitride (SiNx), silicon oxide (SiOx), silicon oxynitride (SiON), or aluminum oxide (Al₂O₃). Since the first inorganic insulating layer 182 and the second inorganic insulating layer 186 are deposited in a low-temperature atmosphere, it may be possible to prevent the light emitting element, which is weak against a high-temperature atmosphere, from being damaged in deposition processes for the first inorganic insulating layer 182 and the second inorganic insulating layer 186.

The organic insulating layer 184 may have a buffering function for reducing stress between layers caused by bending of the display device, and may planarize a step between the layers. The organic insulating layer 184 may be formed on the substrate formed with the first inorganic insulating layer 182, using a non-photosensitive organic insulating material such as acryl resin, epoxy resin, phenolic resin, polyamide resin, polyimide resin, polyethylene, or silicon oxycarbide (SiOC) or a photosensitive organic insulating material such as photoacryl, without being limited thereto.

Alternatively, the encapsulation film 180 may include a first inorganic encapsulation layer, a first organic encapsulation layer, a second inorganic encapsulation layer, a second organic encapsulation layer, and a third inorganic encapsulation layer stacked sequentially.

The first inorganic encapsulation layer, the second inorganic encapsulation layer, and the third inorganic encapsulation layer may serve to block the penetration of moisture or oxygen. The first inorganic encapsulation layer, the second inorganic encapsulation layer, and the third inorganic encapsulation layer may be made of an inorganic material, for example, an inorganic material such as silicon nitride (SiNx), silicon oxide (SiOx), or aluminum oxide (AlOx). However, the present disclosure is not limited thereto.

The first organic encapsulation layer is disposed between the first inorganic encapsulation layer and the second inorganic encapsulation layer, and the second organic encapsulation layer is disposed between the second inorganic encapsulation layer and the third inorganic encapsulation layer. The first organic encapsulation layer and the second organic encapsulation layer may each have a larger thickness than each of the first inorganic encapsulation layer, the second inorganic encapsulation layer, and the third inorganic encapsulation layer in order to adsorb or block particles that may be produced during a process of manufacturing the display device. The first organic encapsulation layer and the second organic encapsulation layer may fill cracks that may be formed in the first inorganic encapsulation layer and the second inorganic encapsulation layer. The first organic encapsulation layer and the second organic encapsulation layer may planarize an upper portion of the first inorganic encapsulation layer and an upper portion of the second inorganic encapsulation layer by covering particles on the first inorganic encapsulation layer and the second inorganic encapsulation layer respectively. For example, the first organic encapsulation layer may planarize an upper portion of the first inorganic encapsulation layer by covering particles on the first inorganic encapsulation layer. For example, the second organic encapsulation layer may planarize an upper portion of the second inorganic encapsulation layer by covering particles on the second inorganic encapsulation layer. The first organic encapsulation layer and the second organic encapsulation layer may be made of an organic material, and for example, epoxy polymer, acrylic polymer, or the like may be used. However, the present disclosure is not limited thereto.

Meanwhile, the encapsulation film 180 is not limited to three or five layers, for example, n layers alternately stacked between inorganic encapsulation layer and organic encapsulation layer (where n is an integer greater than 3) may be included.

In addition, a polarizing plate can be disposed on the encapsulation film 180 in the top-emission type light emitting display device 100 to prevent or reduce contrast reduction caused by external light. When the polarizing plate that blocks external light incident from the outside in the transition direction of light emitted from the emissive layer 230, the contrast of the light emitting display device 100 can be improved.

A cover window can be attached to the top surface of the encapsulation film 180 or the polarizing plate. When the substrate 102 and the cover window are made of flexible material, the flexible or foldable light emitting display device can be implemented.

In addition, color filter layer can be disposed on the light emitting diode D, or between the light emitting diode D and the substrate 102, corresponding to emitting area EA in the pixel region P. For example, when the pixel region P comprises the red (R) pixel region, the green (G) pixel region, and the blue (B) pixel region, the red color filter, the green color filter, and the blue color filter can be disposed corresponding to the red (R) pixel region, the green (G) pixel region, and the blue (B) pixel region, respectively.

In addition, a color conversion layer can be disposed between the light emitting diode D and the color filter layer. The color conversion layer can comprise a red color conversion layer, a green color conversion layer and/or a blue color conversion, each of which corresponding to the red (R) pixel region, the green (G) pixel region and/or the blue (B) pixel region, and converting white (W) light emitted from the light emitting diode D to red color, green color and blue color, respectively. For example, the color conversion layer can comprise quantum dots. The color conversion layer can improve color purity of light emitted from the light emitting diode D. Alternatively, the color conversion layer can be disposed instead of the color filter layer. For example, the color conversion layer is disclosed on the light emitting diode D, without providing the color filter layer. However, the present disclosure are not limited thereto.

The light emitting diode D disposed in the emitting area EA of the pixel region P will be described in more detail. FIG. 3 illustrates a cross-sectional view of a light emitting diode in accordance with an exemplary embodiment of the present disclosure.

As illustrated in FIG. 3, the light emitting diode D comprises first and second electrodes 210 and 220 facing each other and an emissive layer 230 disposed between the first and second electrodes 210 and 220. As an example, the first electrode 210 can be an anode and the second electrode 230 can be a cathode. One of the first electrode 210 and the second electrode 220 can be a transmissive electrode and the other of the first electrode 210 and the second electrode 220 can be a reflective electrode. In one exemplary embodiment, the first electrode 210 can be a reflective electrode and the second electrode 220 can be a transmissive electrode.

The first electrode 210 can comprise a first transparent conductive layer 212 and a second transparent conductive layer 216 each of which can comprise a transparent conductive oxide (TCO) with relatively high work function. In addition, the first electrode 210 can further comprise a reflective metal layer 214 disposed between the first transparent conductive layer 212 and the second transparent conductive layer 216. Alternatively, the first electrode 210 can consist of the first transparent conductive layer 212 and/or the second transparent conductive layer 216.

As an example, each of the first transparent conductive layer 212 and the second transparent conductive layer 216 can comprise, but is not limited to, a doped or an undoped metal oxide such as indium-tin-oxide (ITO), indium-zinc-oxide (IZO), indium-tin-zinc-oxide (ITZO), tin oxide (SnO₂), indium oxide (In₂O₃), cadmium:zinc oxide (Cd:ZnO), fluorine:tin oxide (F:SnO₂), indium:tin oxide (In:SnO₂), gallium:tin oxide (Ga:SnO₂) and aluminum:zinc oxide (Al:ZnO; AZO).

The reflective electrode layer 214 can comprise metal material with high light reflectivity. In one exemplary embodiment, the reflective electrode 214 can comprise, but is not limited to, silver (Ag) and/or aluminum-palladium-copper (APC) alloy. For example, the first electrode 210 can have a triple-layered structure of ITO-AG-ITO or ITO-APC-ITO in the top-emission type light emitting diode D.

The second electrode 220 of the transmissive electrode can comprise a metal or a metal halide with relatively low work function. As an example, the second electrode 220 can comprise, but is not limited to, calcium (Ca), barium (Ba), calcium/aluminum (Ca/Al), lithium fluoride/calcium (LiF/Ca), lithium fluoride/aluminum (LiF/Al), barium fluoride/aluminum (BaF₂/Al), cesium fluoride/aluminum (CsF/Al), calcium carbonate/aluminum (CaCO₃/Al), barium fluoride/calcium/aluminum (BaF₂/Ca/Al), aluminum (Al), magnesium (Mg), aluminum/magnesium (Al/Mg), gold:magnesium (Au:Mg) and/or silver: magnesium (Ag:Mg). For example, each of the first electrode 210 and the second electrode 220 can have a thickness of, but is not limited to, about 30 nm to about 300 nm. For example, each of the first electrode 210 and the second electrode 220 can have a thickness of, but is not limited to, about 100 nm to about 200 nm.

The emissive layer 230 can comprise an emitting material layer (EML) 340. In addition, the emissive layer 230 can further comprise at least one of a hole transport layer (HTL) 320 disposed between the first electrode 210 and the EML 340 and an electron transport layer (ETL) 360 disposed between the EML 340 and the second electrode 220. The emissive layer 230 can further comprise at least one of a hole injection layer (HIL) 310 disposed between the first electrode 210 and the HTL 320 and an electron injection layer (EIL) 370 disposed between the ETL 360 and the second electrode 220. Alternatively or additionally, the emissive layer 230 can further comprise at least one of an electron blocking layer (EBL) 330 disposed between the HTL 320 and the EML 340 and a hole blocking layer (HBL) 350 disposed between the EML 340 and the ETL 360.

The HIL 310 facilitates hole injections to the EML 340 from the first electrode 210. For example, the hole injecting material in the HIL 310 can comprise, but is not limited to, poly (ethylenedioxythiophene):polystyrenesulfonate (PEDOT:PSS), N,N′-diphenyl-N,N′-bis(1-naphtyl)-1,1′-biphenyl-4,4″-diamine (NPD, NPB), 4,4′,4″-Tris(N,N-diphenyl-amino)triphenylamine (NATA), 4,4′,4″-Tris(N-(naphthalene-1-yl)-N-phenyl-amino)triphenylamine (1T-NATA), 4,4′,4″-Tris(N-(naphthalene-2-yl)-N-phenyl-amino)triphenylamine (2T-NATA), Copper phthalocyanine (CuPc), 1,3,5-Tris[4-(diphenylamino)phenyl]benzene (TDAPB), 1,4,5,8,9,11-Hexaazatriphenylenehexacarbonitrile (Dipyrazino[2,3-f:2′3′-h]quinoxaline-2,3,6,7,10,11-hexacarbonitrile; HAT-CN), 2,3,5,6-tetrafluoro-7,7,8,8-tetracyanoquinodimethane (F4-TCNQ), 1,3,4,5,7,8-hexafluorotetracaynonaphthoquinodimethane (F6-TCNNQ) and/or combinations thereof.

In another exemplary embodiment, the HIL 310 can comprise a hole injection host of a hole transporting material described below, and a hole injecting material (e.g., HAT-CN, F4-TCNQ and/or F6-TCNNQ). In certain exemplary embodiments, the HIL 310 can be omitted in accordance with a structure of the light emitting diode D.

The HTL 320 transfers holes into the EML 340. The HTL 320 can comprise organic material or inorganic material.

In one exemplary embodiment, the organic hole transporting material in the HTL 320 can comprise, but is not limited to, 4,4,4′-N,N′-dicarbazolyl-biphenyl (CBP), NPD, N,N′-diphenyl-N,N′-bis(3-methylphenyl)-(1,1′-biphenyl)-4,4′-diamine (TPD), N,N′-bis(3-methylphenyl)-N,N′-bis(phenyl)-spiro (spiro-TPD), N,N′-di(4-(N,N′-diphenyl-amino)phenyl)-N,N′-diphenylbenzidine (DNTPD), 4,4′,4″-tris(N-carbazolyl)-triphenylamine (TCTA), (tris(3-methylphenylphenylamino)-triphenylamine (m-MTDATA), poly (9,9′-dioctylfluorenyl-2,7-diyl)-co-(4,4′-(N-(4-sec-butylphenyl)diphenylamine (TFB), Poly (4-butylphenyl-dipnehyl amine (poly-TPD), and/or combinations thereof.

In another exemplary embodiment, the inorganic hole transporting material in the HTL 320 can comprise, but is not limited to, metal oxide such as NiO, MoO₃, Cr₂O₃, Bi₂O₃, and/or p-type ZnO; non-oxide equivalents such as thiocyan copper (CuSCN), Mo₂S, and/or GaN; and/or combinations thereof.

In one exemplary embodiment, the EML 340 can comprise organic light emitting material. As an example, the EML 340 can comprise organic light emitting materials emitting blue color, green color, red color and/or yellow-green color. When the EML 340 comprises the organic light emitting material, the EML 340 can comprise a host and a dopant. The dopant can comprise at least one of phosphorescent material, fluorescent material and delayed fluorescent material. However, the present disclosure is not limited thereto.

In another exemplary embodiment, the EML 340 can comprise inorganic luminescent particles. For example, the inorganic luminescent particles can comprise quantum dots (QDs) and/or quantum rods (QRs). The quantum dots or the quantum rods are nano inorganic particles emitting light as the unstable electrons drops conduction band energy levels to valence band energy levels.

In one exemplary embodiment, the inorganic luminescent particles can have a single structure. In another exemplary embodiment, the inorganic luminescent particles can have a core/shell hetero structure and can comprise a plurality of organic ligands that are bound to or free from the surface of the shell. In this case, the shell can have one shell or multiple shells.

The ETL 360 transfers electrons into the EML 340. The ETL 360 can comprise organic material or inorganic material.

In one exemplary embodiment, the organic electron transporting material in the ETL 360 can comprise, but is not limited to, oxazole-containing compounds, iso-oxazole-containing compounds, triazole-containing compounds, iso-thiazole-containing compounds, oxadiazole-containing compounds, thiadizaole-containing compounds, phenanthroline-containing compounds, perylene-containing compounds, benzoxazole-containing compounds, benzothiazole-containing compounds, benzimidazole-containing compounds, pyrene-containing compounds, triazine-containing compounds and/or aluminum-containing complexes. However, the present disclosure is not limited thereto.

As an example, the organic electron transporting material in the ETL 360 can comprise, but is not limited to, Tris-(8-hydroxyquinoline aluminum (Alq₃), 2-biphenyl-4-yl-5-(4-t-butylphenyl)-1,3,4-oxadiazole (PBD), spiro-PBD, lithium quinolate (Liq), 1,3,5-Tris (N-phenylbenzimidazol-2-yl)benzene (TPBi), Bis(2-methyl-8-quinolinolato-N1,O8)-(1,1′-biphenyl-4-olato)aluminum (BAlq), 4,7-diphenyl-1,10-phenanthroline (Bphen), 2,9-Bis(naphthalene-2-yl)4,7-diphenyl-1,10-phenanthroline (NBphen), 2,9-Dimethyl-4,7-diphenyl-1,10-phenathroline (BCP), 3-(4-Biphenyl)-4-phenyl-5-tert-butylphenyl-1,2,4-triazole (TAZ), 4-(Naphthalen-1-yl)-3,5-diphenyl-4H-1,2,4-triazole (NTAZ), 1,3,5-Tri (p-pyrid-3-yl-phenyl)benzene (TpPyPB), 2,4,6-Tris(3′-(pyridin-3-yl)biphenyl-3-yl)1,3,5-triazine (TmPPPyTz), Poly [9,9-bis(3′-((N,N-dimethyl)-N-ethylammonium)-propyl)-2,7-fluorene]-alt-2,7-(9,9-dioctylfluorene)] (PFNBr), tris (phenylquinoxaline (TPQ), diphenyl[4-(triphenylsilyl)phenyl]phosphine oxide (TSPO1), 2-[4-(9,10-Di-2-naphthalen2-yl-2-anthracen-2-yl)phenyl]-1-phenyl-1H-benzimidazole (ZADN), and/or combinations thereof. However, the present disclosure is not limited thereto.

In another exemplary embodiment, the inorganic electron transporting material in the ETL 360 can comprise, but is not limited to, metal/non-metal oxides such as titanium dioxide (TiO₂), zinc oxide (ZnO), zinc magnesium oxide (ZnMgO), zirconium oxide (ZrO), tin oxide (SnO₂), tungsten oxide (WO₃), tantalum oxide (Ta₂O₃), hafnium oxide (HfO₃), aluminum oxide (Al₂O₃), zirconium silicon oxide (ZrSiO₄), barium titanium oxide (BaTiO₃) and/or barium zirconium oxide (BaZrO₃), each of which is undoped or doped with Al, Mg, In, Li, Ga, Cd, Cs, Cu and the likes; semiconductor particles such as CdS, ZnSe and/or ZnS each of which is undoped or doped with Al, Mg, In, Li, Ga, Cd, Cs, Cu and the likes; nitrides such as Si₃N₄; and/or combinations thereof. However, the present disclosure is not limited thereto.

The EIL 370 facilitates electron injections from the second electrode 220 to the EML 340. In one exemplary embodiment, electron injecting material in the EIL 370 can comprise, but is not limited to, inorganic materials such as metal halides in which metal such as Al, Cd, Cs, Cu, Ga Ge, In and/or Li doped or linked with fluorine; and/or metal oxides such as TiO₂, ZnO, ZrO, SnO₂, WO₃, Ta₂O₃ undoped or doped with Al, Mg, In, Li, Ga, Cd, Cs, Cu, and the likes. In another exemplary embodiment, the organic electron injecting material in the EIL 370 can comprise, but is not limited to, organometallic material such as Liq, lithium benzoate and sodium stearate. In some exemplary embodiments, the EIL 370 can be omitted in accordance with the structure of the light emitting diode D. However, the present disclosure is not limited thereto.

As an example, electron blocking material in the EBL 330 can comprise, but is not limited to, TCTA, Tris[4-(diethylamino)phenyl]amine, m-MTDATA, 1,3-bis(N-carbazolyl)benzene (mCP), 3,3′-Di(9H-carbzol-9-yl)-1,1′-biphenyl (mCBP), N-(biphenyl-4-yl)-9,9-dimethyl-N-(4-(9-phenyl-9H-carbazol-3-yl)phenyl)-9H-fluoren-2-amine, Di-[4-(N,N-di-p-tolyl-amino)-phenyl]cyclohexane (TAPC) and/or combinations thereof. However, the present disclosure is not limited thereto.

Hole blocking material in the HBL 350 can comprise oxadiazole-containing compounds, triazole-containing compounds, phenanthroline-containing compounds, benzoxazole-containing compounds, benzothiazole-containing compounds, benzimidazole-containing compounds, triazine-containing compounds, and/or combinations thereof. However, the present disclosure is not limited thereto.

In one exemplary embodiment, the hole blocking material in the HBL 350 can comprise material with lower HOMO (highest occupied molecular orbital) energy level than the material in the EML 340. For example, the hole blocking material in the HBL 350 can comprise, but is not limited to, BCP, BAlq, Alq3, PBD, spiro-PBD, Liq, bis-4,6-(3,5-di-3-pyridylphenyl)-2-methylpyrimidine (B3PYMPM), bis[2-(diphenylphosphino)phenyl]ether oxide (DPEPO), 9-(6-(9H-carbazol-9-yl)pyridin-3-yl)-9H-3,9′-bicarbazole, TSPO1, and/or combinations thereof. However, the present disclosure is not limited thereto.

The light emitting diode D has a single emitting part in FIG. 3. Alternatively, the light emitting diode can have a tandem structure with multiple emitting parts. In this case, each emitting part can comprise an emitting material layer, and optionally, a hole injection layer, a hole transport layer, an electron blocking layer, an electron transport layer and/or an electron injection layer. Each emitting part can be connected through a charge generation layer. The charge generation layer can have a junction structure of a P-type charge generation layer and an N-type charge generation layer.

Light shielding or blocking efficiency and luminous efficiency can be improved in the light emitting display device 100. FIG. 4 is a schematic view illustrating that light reflected from the metal electrode and reflective electrode is blocked by a column spacer with a light-shielding material in a light emitting display device in accordance with an exemplary embodiment of the present disclosure.

As illustrated in FIG. 4, at least one of the first column spacer 172 and the second column spacer 174 comprises light-shielding material 172a and/or 174a. The external light entering the first column spacer 172 and/or the second column spacer 174 can be absorbed and blocked by the first light-shielding material 172a and/or the second light-shielding material 174a each of which is contained in the first column spacer 172 and/or the second column spacer 174, respectively. For example, the first light-shielding material 172a is contained in the first column spacer 172, and the second light-shielding material 174a is contained in the second column spacer 174. However, the present disclosure is not limited thereto. For example, the first light-shielding material 172a is contained in the first column spacer 172 and the second column spacer 174; for example, the second light-shielding material 174a is contained in the first column spacer 172 and the second column spacer 174; for example, the first light-shielding material 172a is contained in the second column spacer 174, and the second light-shielding material 174a is contained in the first column spacer 172. In addition, the reflective light reflected from the metal electrodes and metal lines such as the reflective electrode layer 212, the source/drain electrodes 152, 154 can be absorbed and blocked by the first light-shielding material 172a and/or the second light-shielding material 174a each of which is contained in the first column spacer 172 and/or the second column spacer 174, respectively. For example, the first light-shielding material 172a is contained in the first column spacer 172, and the second light-shielding material 174a is contained in the second column spacer 174. However, the present disclosure is not limited thereto. For example, the first light-shielding material 172a is contained in the first column spacer 172 and the second column spacer 174; for example, the second light-shielding material 174a is contained in the first column spacer 172 and the second column spacer 174; for example, the first light-shielding material 172a is contained in the second column spacer 174, and the second light-shielding material 174a is contained in the first column spacer 172.

In one exemplary embodiment, the first column spacer 172 and/or the second column spacer 174 can have a refractive index n2 lower than refractive index n1 of the first electrode 220. Among the external light incident to the first column spacer 172 and/or the second column spacer 174, each of which is a thin medium, from the first electrode 220, which is a dense medium, light exceeding the critical angle can be totally reflected. Accordingly, the external light can be further prevented from being incident on the light-emitting diode D and the thin film transistor Tr.

As at least one of the first column spacer 172 and the second column spacer 174 comprise the light-shielding material 172a and/or 174a, it is possible to minimize or prevent threshold voltage changes of the thin film transistor caused by the external light. In addition, the external light reflectivity decreases in the light emitting display device 100 so that the light emitting display device 100 with beneficial light efficiency can be realized.

As described above, at least one of the first column spacer 172 and the second column spacer 174 disposed on the bank layer 164 can comprise the light-shielding materials 172a and 174a. In one exemplary embodiment, the first column spacer 172 with relatively wide surface area can comprise the first light-shielding material 172a. In another exemplary embodiment, each of the first column spacer 172 and the second column spacer 174 can comprise the light-shielding materials 172a and 174a, respectively. However, the present disclosure is not limited thereto. For example, the first light-shielding material 172a is contained in the first column spacer 172, and the second light-shielding material 174a is contained in the second column spacer 174. However, the present disclosure is not limited thereto. For example, the first light-shielding material 172a is contained in the first column spacer 172 and the second column spacer 174; for example, the second light-shielding material 174a is contained in the first column spacer 172 and the second column spacer 174; for example, the first light-shielding material 172a is contained in the second column spacer 174, and the second light-shielding material 174a is contained in the first column spacer 172.

The first light-shielding material 172a in the first column spacer 172 and/or the second light-shielding 174a in the second column spacer 174 can act as light absorption, and is not particularly limited. In one exemplary embodiment, the first light-shielding material 172a in the first column spacer 172 and/or the second light-shielding material 174a in the second column spacer 174 can comprise black colorants such as black pigments and/or black dyes.

In another exemplary embodiment, the first light-shielding material 172a in the first column spacer 172 and/or the second light-shielding material 172a in the second column spacer 174 can comprise, but is not limited to, carbon black, carbon nanotube (CNT), graphene, organic black, black dyes, azo-type dyes or pigments, carbon materials, hybrid type of R/G/G pigments/dyes, and/or multi-layered thin film material.

Alternatively, any organic material that is oxidized after photoresist process comprising exposures and development processes, or in the course of post-baking process of the first column spacer 172 and/or the second column spacer 174 and that is converted to black color can be used as the light-shielding materials 172a and 174a.

In one exemplary embodiment, at least one of the first column spacer 172 and the second column spacer 174 can be disposed on the bank layer 164, or at least one of the first column spacer 172 and the second column spacer 174 is formed by coating photosensitive composition for forming spacer of Millbase comprising the light-shielding material 172a or 174a, a binder, a solvent and a dispersant on the bank layer 164 and the emissive layer 230, and by proceeding photoresist (PR) process using the half-tone mask. In another exemplary embodiment, one of the first column spacer 172 and the second column spacer 174 does not comprise the light-shielding material 172a or 174a. In this case, the first column spacer 172 or the second column spacer 174 can be disposed on the bank layer 164, or at least one of the first column spacer 172 and the second column spacer 174 is formed by coating photosensitive composition for forming spacer of Millbase comprising a binder, a solvent and a dispersant on the bank layer 164 and the emissive layer 230, and by proceeding photoresist (PR) process using the half-tone mask. However, the present disclosure is not limited thereto.

For example, the first column spacer 172 can be disposed on the bank layer 164 using negative photoresist process. The second column spacer 174 can be disposed on the first column spacer using negative photoresist process.

In one exemplary embodiment, the bank layer 164 may not comprise any light-shielding material such as black materials. In other words, the bank layer 164 can be a non-black bank layer. For example, the bank layer 164 can be a white bank layer comprising only radiant materials. In another exemplary embodiment, the bank layer 164 can be a gray bank layer comprising the radiant materials and the light-shielding material. The non-black bank layer 164 can minimize or prevent dead pixels in the pixel region P, and thus, the display quality of the light emitting display device 100 can be improved.

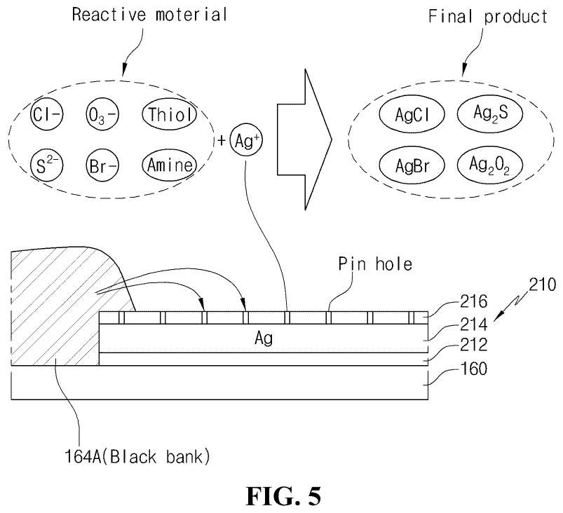

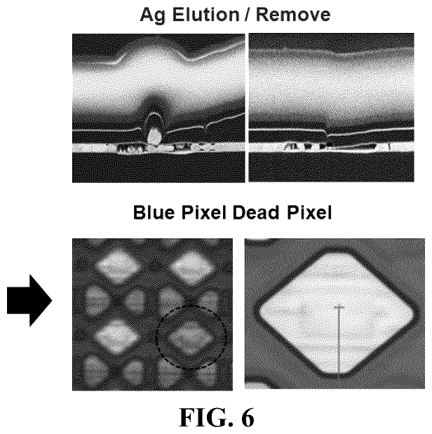

FIG. 5 is a schematic view illustrating a reaction between a composition with black colorant for a bank layer and silver of the reflective electrode in a conventional light emitting display device. FIG. 6 illustrates dead pixel in a pixel area by the reaction between the composition with black colorant for a bank layer and silver of the reflective electrode in a conventional light emitting display device.

As illustrated in FIG. 5, a black bank layer 164A is disposed by coating Millbase with black colorant, a polymer binder, a dispersant and a solvent on the first electrode 210 and the non-emission area, and proceeding negative photoresist process. In dispersing black colorant in the Millbase with the dispersant, the polymer resin and the dispersant should be polymerized. In the dispersing of the black colorant and polymerizing the polymer resin and the dispersant, impurities enter the Millbase, and thus, the Millbase including the black colorant is susceptible to impurity inflows.

In addition, in the curing process for forming the black bank layer 164A, metal components (e.g., Ag⁺) of the reflective electrode layer 214 react with reactive components (e.g., Cl⁻, O₃⁻, S²⁻, Br, thiol, amine, and the likes) within the Millbase for forming the black bank layer 164A in exposure area of the reflective electrode layer 214 to covert to AgCl, Ag₂S, Ag₂O₂, and the likes. As illustrated in FIG. 6, as the metal components in the reflective electrode layer 214 are eluted or removed, dead pixel is occurred in some pixel regions Ps.

In addition, as the contents of the black colorants in the black bank layer 164A increases, process problems such as fine patterns and residues occur. Also, problems occur in terms of outgas and reliability due to byproducts added other than the black colorant.

On the other hand, the first column spacer 172 and the second column spacer 174 comprising the light-shielding material 172a or 174a is spaced apart from the reflective electrode layer 214 of the first electrode 210. In addition, the bank layer 164 contacting the reflective electrode layer 214 does not comprise any light-shielding material such as black colorant, or little light-shielding material.

In forming the non-black bank layer 164, reaction between the impurities entering the Millbase for forming the non-black bank layer 164 and the metal component of the reflective electrode layer 214 hardly occurs or is suppressed. Accordingly, it is possible to minimize or prevent dead pixel formation in the pixel region P caused by the loss or elution of the metal components of the reflective electrode layer 214.

In addition, as the bank layer 164 does not comprise any light-shielding material or comprises little light-shielding material, it is possible to minimize process problems owing to micro patterns and/or residues. Also, problems arise in terms of outgassing and reliability due to by-products added in addition to the light-shielding material. Further, it is possible to prevent or reduce side effects (abnormal operations of metal layers and oxide semiconductor elements) caused by light leakage and reflection when the light emitting diode D emits light.

In one exemplary embodiment, the bank layer 164 can be a white bank layer comprising white heat dissipating particles. As an example, the white heat dissipating particles can comprise a first (nano) heat dissipating particle with a zero-dimensional shape and/or a second (nano) heat dissipating particle with a one dimensional shape, a two dimensional shape or a three dimensional shape. The white bank layer 164 can be formed by photoresist process using a photosensitive composition comprising a binder resin and/or the white heat dissipating particles dispersed in the solvent.

In another exemplary embodiment, the bank layer 164 can be a gray bank layer comprising the white heat dissipating particles and light-shielding material. The gray bank layer 164 can be formed by photoresist process using a photosensitive composition comprising a binder resin and/or the white heat dissipating particles and the light-shielding material dispersed in the solvent. In one exemplary embodiment, the white heat dissipating particles and the light-shielding material in the gray bank layer 164 can be mixed, but is not limited to, with weight ratio of about 2:8 to about 8:2, for example, about 5:5 to about 8:2.

For example, the binder resin in which the heat dissipating particles, and/or the heat dissipating particles and the heat-shielding materials is dispersed can be dissolved in an alkaline soluble aqueous solution, and can have one or more thermosetting functional groups (e.g., acrylate group, methacrylate group, vinyl group, etc.).

As an example, the white heat dissipating particle included in the bank layer 164 can comprise, but is not limited to, a nanotube with a one dimensional shape, a nanowire or a nano sheet with a two dimensional shape, and/or nano particles with a three dimensional shape such as such as a hexagonal shape and/or a cubic shape. However, the present disclosure is not limited thereto.

For example, the white heat dissipating particles included in the bank layer 164 can comprise, but is not limited to, metal material, carbon-containing material, ceramic materials such as inorganic oxides, inorganic nitrides, inorganic arsenides and/or inorganic carbides, and combinations thereof.

As an example, the metal material as the heat dissipating particles can be selected from, but is not limited to, aluminum (Al), gold (Au), copper (Cu), silver (Ag), and/or any combinations thereof. The carbon-containing material as the heat dissipating particles can be selected from, but is not limited to, graphite, graphene, carbon nanotube (CNT), and/or any combinations thereof.

The inorganic oxides as the heat dissipating particles can be selected from, but is not limited to, Al₂O₃, SiO₂, MgO, ZnO, ZrO₂, and/or any combinations thereof. The inorganic nitrides as the heat dissipating particles can be selected from, but is not limited to, aluminum nitride (AlN), boron nitride (BN), and/or any combinations thereof. The inorganic arsenides as the heat dissipating particles can comprise, but is not limited to, born arsenide (BAs).

For example, the white heat dissipating particle can comprise boron nitride (BN). Boron nitride (BN) is referred to as white graphene, and consists of boron with a similar structure to graphene and nitrogen (N). On the contrary, boron nitride (BN) is an electrical insulation since no free electron is present unlikely to graphene, and has very excellent thermal conductivity owing to electron-phonon interaction.

In addition, boron nitride (BN) has very beneficial scattering property because boron nitride (BN) has very high refractive indices (e.g., hexagonal boron nitride (h-BN) has refractive index of about 1.8, cubic boron nitride (cBN) has refractive index of about 2.1). Accordingly, it is possible to control the reflectivity in the light emitting display device 100 by applying boron nitride (BN) as the heat dissipating particles in the bank layer 164. In addition, boron nitride (BN) has beneficial thermal conductivity as metal and excellent thermal dissipation property.

As an example, the heat dissipating particle in the bank layer 164 can be selected from, but is not limited to, any one of boron nitride nanotube (BNNT), boron nitride nanowire, boron nitride nano sheet (BNNS), hexagonal boron nitride (h-BN), cubic boron nitride (c-BN) and/or combinations thereof.

In another exemplary embodiment, the heat dissipating particles in the bank layer 164 can be selected from, but is not limited to, any one of a nanoparticle, a nanotube, a nanowire, a nano sheet and/or combinations thereof. For example, the heat dissipating particles in the bank layer 164 can be selected from, but is not limited to, any one of a boron nitride nanoparticle, a boron nitride nanotube, a boron nitride nanowire, a born nitride nano sheet and/or combinations thereof. Alternatively, the white heat dissipating particles in the bank layer 164 can comprise the nano particle mixed with at least one of the nanowire and the nano sheet. However, the present disclosure is not limited thereto.

The light-shielding material in the gray bank layer 164 can be identical to the first light-shielding material 172a in the first column spacer 172 and/or the second light-shielding material 174a in the second column spacer 174. For example, the light-shielding material in the gray bank layer 164 can be identical to the first light-shielding material 172a in the first column spacer 172; for example, the light-shielding material in the gray bank layer 164 can be identical to the second light-shielding material 174a in the second column spacer 174; For example, the light-shielding material in the gray bank layer 164 can be identical to both the first light-shielding material 172a in the first column spacer 172 and the second light-shielding material 174a in the second column spacer 174. However, the present disclosure is not limited thereto, the light-shielding material in the gray bank layer 164 can be different from both the first light-shielding material 172a in the first column spacer 172 and the second light-shielding material 174a in the second column spacer 174.

In one exemplary embodiment, the light-shielding material in the gray bank layer 164 can comprise black colorants such as black pigments and/or black dyes. In another exemplary embodiment, the light-shielding material in the gray bank layer 164 can comprise, but is not limited to, carbon black, carbon nanotube (CNT), graphene, organic black, black dyes, azo-type dyes or pigments, carbon materials, hybrid type of R/G/G pigments/dyes, and/or multi-layered thin film material. Alternatively, any organic material that is oxidized after photoresist process comprising exposures and development processes, or in the course of post-baking process of the gray bank layer 164 and that is converted to black color can be used as the light-shielding materials in the bank layer 164.

In another exemplary embodiment, the first electrode 210 does not comprise the reflective electrode layer 214, and can consist of the first transparent conductive layer 212 and/or the second transparent conductive layer 216. In this case, the bank layer 164 can be a black bank layer comprising the light-shielding material. The first electrode 210 does not comprise any metal components even when the bank layer 164 forms the black bank layer comprising the light-shielding material. As reaction between the impurities in the bank layer 164 and the metal component in the first electrode 210 is not occurred, it is possible to minimize and prevent dead pixels caused by the metal component losses or eluents.

As an example, the bank layer 164 in addition to the first column spacer 172 and/or the second column spacer 174 can comprises the light-shielding material. It is possible to prevent or reduce regular reflection and diffuse reflection from metal electrodes and metal lines such as source and drain electrodes 152 and 154, and to improve reflection visibility and light scatting properties. In addition, it is possible to block efficiently light leakage from the metal lines or adjacent pixel regions, and thereby, improving image quality by introducing the black bank layer comprising the light-shielding material.

### Second Example

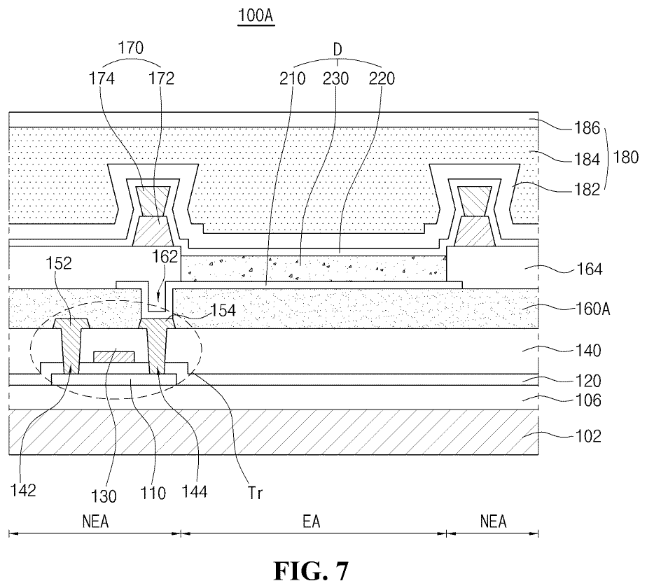

In the first Example, the light emitting display device includes at least one column spacer comprising the light-shielding material. Hereafter, a light emitting display device that can absorb efficiently the reflective light and/or the external light will be described. FIG. 7 illustrates a cross-sectional view of a light emitting display device in accordance with another exemplary embodiment of the present disclosure.

As illustrated in FIG. 7, a light emitting display device 100A comprise a substrate 102 defining an emission area EA and a non-emission area NEA, a thin film transistor Tr disposed in the non-emission area NEA on the substrate 102, a light emitting diode D connected to the thin film transistor Tr and disposed in the emission area EA, a bank layer 164 disposed correspondingly to the non-emission area NEA, a column spacer 170 disposed on the bank layer 164 and comprising a first column spacer 172 and a second column spacer 174 with different shapes.

The substrate 102 can be a glass substrate, a flexible substrate or a polymer plastic substrate. For example, the substrate 102 can comprise a thin plastic film that can be made of PEN, PET, PBT, polysilane, polysiloxane, polysilazane, polycarbosilane, polyacrylate, polymethacrylate, polymethylacrylate, PMMA, polyethylacrylate, polyethylmethacrylate, COC, COP, PE, PP, PI, PS, PEE, PES, PTFE, PVC, PC, PVDF, PFA, SAN, combinations thereof and/or copolymers thereof. Alternatively, the substrate 102 can be a glass substrate.

A buffer layer 106 is disposed on the substrate 102, and a thin film transistor Tr is disposed correspondingly to the pixel region P on the buffer layer 106. For example, the first buffer layer 106 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto. In some exemplary embodiment, the buffer layer 106 can be omitted.

A semiconductor layer 110 can be disposed on the buffer layer 106. As an example, the semiconductor layer 110 can comprise oxide semiconductor materials and/or polycrystalline silicon, but the present disclosure is not limited thereto.

A gate insulating layer 120 comprising an insulating material, for example, inorganic insulating material such as silicon oxide (SiOₓ, wherein 0<x≤2) or silicon nitride (SiNₓ, wherein 0<x≤2), is disposed on the semiconductor layer 110.

A gate electrode 130 comprising a conductive material such as metal is disposed correspondingly to a center of the semiconductor layer 110 on the gate insulating layer 120. A interlayer insulating layer 140 comprising an insulating materials, for example, inorganic insulating material such as silicon oxide (SiOₓ, wherein 0<x≤2) or silicon nitride (SiNₓ, wherein 0<x≤2), or organic insulating material such as benzocyclobutene or photo-acryl is disposed on the gate electrode 130.

The interlayer insulating layer 140 has first and second semiconductor layer contact holes 142 and 144 that expose or do not cover sides of the semiconductor layer 110. The first and second semiconductor layer contact holes 142 and 144 are disposed on opposite sides of the gate electrode 130 and spaced apart from the gate electrode 130.

A source electrode 152 and a drain electrode 154, each of which is made of conductive material such as a metal, are disposed on the interlayer insulating layer 140. The source electrode 152 and the drain electrode 154 are spaced apart from each other on opposing sides of the gate electrode 130, and contact both sides of the semiconductor layer 110 through the first and second semiconductor layer contact holes 142 and 144, respectively.

The semiconductor layer 110, the gate electrode 130, the source electrode 152 and the drain electrode 154 constitute the thin film transistor Tr, which acts as a driving element.

A passivation layer 160A is disposed on the source and drain electrodes 152 and 154. The passivation layer 160A covers the thin film transistor Tr on the entire substrate 102. The passivation layer 160A has a flat top surface and a drain contact hole (or a contact hole) 162 that exposes or does not cover the drain electrode 154 of the thin film transistor Tr. Alternatively, another passivation layer can be disposed between the source electrode 152, the drain electrode 154 and the interlayer insulating layer 140, and the passivation layer 160.

A light emitting diode D is disposed on the passivation layer 160. The light emitting diode D comprises a first electrode 210 connected to the drain electrode 154 of the thin film transistor Tr, a second electrode 220 facing the first electrode 210, and an emissive layer 230 disposed between the first electrode 210 and the second electrode 220.

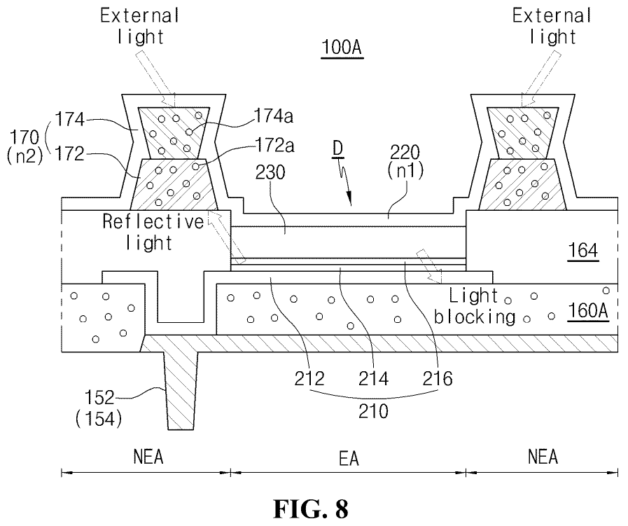

The first electrode 210 that is disposed separately in each pixel region can be an anode and comprise conductive material with high work function value. In one exemplary embodiment, the first electrode 210 can have a single-layered structure of a transparent conductive layer of TCO. In another exemplary embodiment, the first electrode 210 can comprise at least one transparent conductive layer 212 or 216 (FIG. 8) and a reflective electrode layer 214 (FIG. 8) disposed on or under the at least one transparent conductive layer.

A bank layer 164 covering an edge of the first electrode 210 is disposed on the passivation layer 160A. The bank layer 164 exposes a center of the first electrode 210 corresponding to each pixel region P. For example, the bank layer 164 can comprise the same material as the passivation layer 160A.

A column spacer 170 is disposed on the bank layer 164. The column spacer 170 can comprise a first column spacer 172 and a second column spacer 174 disposed sequentially on the bank layer 164 and having different cross-sectional shapes. For example, the first column spacer 172 disposed on the bank layer 164 can have a cross-sectional shape of which width decreases gradually toward the bank layer 164. The second column spacer 174 disposed on the first column spacer 172 can have a cross-sectional shape of which width decreases gradually toward the bank layer 164. Accordingly, adhesion performance between the column spacer 172 and an encapsulation layer 180 can be improved. In addition, the bending stress to an emissive layer 230 can be alleviated in folding the flexible light emitting diode D.

The emissive layer 230 is disposed in the emission area EA on the first electrode 210. In one exemplary embodiment, the emissive layer 230 can be disposed sequentially on the first electrode 210 disposed in the emission area EA, and the bank layer 164 and the column spacer 170 each of which is disposed in the non-emission area NEA. In other words, the emissive layer 230 can be disposed entirely in the display area, similar to a second electrode 220.

In one exemplary embodiment, the emissive layer 230 can have a single-layered structure of an emitting material layer (EML). In another exemplary embodiment, the emissive layer 230 can further comprise a hole injection layer (HIL), a hole transport layer (HTL) and/or an electron blocking layer (EBL) disposed between the first electrode 210 and the EML. In addition, the emissive layer 230 can further comprise a hole blocking layer (HBL), an electron transport layer (ETL), an electron injection layer (EIL) and/or a charge generation layer (CGL) disposed between the EML and the second electrode 220. The emissive layer 230 can comprise two or more emitting part to form a tandem structure, or comprise only single emitting part.

A second electrode 220 is disposed on the emissive layer 230, the bank layer 164 and the column spacer 170. The second electrode 210 is disposed entirely in the display area, and can have materials with relatively low work function values to form a cathode injecting electrons to the emissive layer 230. The light emitted from the emissive layer 130 can be passed through the second electrode 220 in the light emitting display device 100A. In this case, the second electrode 220 can be thin to pass through the light emitted from the emissive layer 230.

An encapsulation layer 180 can be disposed on the second electrode 220 to prevent or reduce external moistures to penetrate into the light emitting diode D. For example, the encapsulation layer 180 can have, but is not limited to, a lamination structure of a first inorganic insulating layer 182a, an organic insulating layer 184 and a second inorganic insulating layer 186. In addition, a polarizing plate for reducing external light reflection can be disposed on the encapsulation layer 180, and a cover widow can be disposed on the encapsulation film 180 or the polarizing plate. For example, the polarizing plate can be a circular polarizing plate.

FIG. 8 is a schematic view illustrating that light reflected from the metal electrode and reflective electrode is blocked by a column spacer with a light-shielding material in a light emitting display device in accordance with another exemplary embodiment of the present disclosure.

As illustrated in FIG. 8, at least one of the first column spacer 172 and the second column spacer 174 can comprise a light-shielding material 172a or 174a. The external light that is incident to the first column spacer 172 and/or the second column spacer 174 in the light emitting display device 100A can be absorbed and blocked by the first light-shielding material 172a and/or the second light-shielding material 174a each of which can be included in the first column spacer 172 and/or the second column spacer 174. In addition, the reflective light reflected from the reflective electrode layer 212 can be absorbed and blocked by the first light-shielding material 172a and/or the second light-shielding material 174a each of which can be included in the first column spacer 172 and/or the second column spacer 174.

In accordance with exemplary exemplary embodiment, the passivation layer 160A disposed between the thin film transistor Tr and the light emitting diode D can comprise a light-shielding material. The light emitted toward the bottom of the light emitting diode D can be blacked by the passivation layer 160A. The light emitted toward the bottom of the light emitting diode D cannot be incident metal electrodes and/or metal lines such as the source/drain electrodes 152 and 154, and can be blocked efficiently.

As an example, the light-shielding material in the passivation layer 160A can be the same as the first light-shielding material 172a and/or the second light-shielding material 174a. In one exemplary embodiment, the light-shielding material in the passivation layer 160A can comprise black colorants such as black pigments and/or black dyes. In another exemplary embodiment, the light-shielding material in the passivation layer 160A can comprise, but is not limited to, carbon black, carbon nanotube (CNT), graphene, organic black, black dyes, azo-type dyes or pigments, carbon materials, hybrid type of R/G/G pigments/dyes, and/or multi-layered thin film material.

Alternatively, any organic material that is oxidized after photoresist process comprising exposures and development processes, or in the course of post-baking process of the passivation layer 160A and that is converted to black color can be used as the light-shielding material in the passivation layer 160A.

In one exemplary embodiment, the passivation layer 160A can be formed by curing a photo-reactive composition comprising the light-shielding material, a binder polymer dispersing the light-shielding material and/or a solvent. The binder polymer that can be included in the passivation layer 160A can comprise, but is not limited to, polyacrylate-containing resins, epoxy-containing resins, phenol-containing resins, polyamide-containing resins, polyimide-containing resins, unsaturated polyester-containing resins, poly-phenylene-ether-containing resins, poly-phenylene-sulfide-containing resins, benzocyclobutene, copolymers thereof and/or combinations thereof. The passivation layer 160A can have a single-layered structure or a multiple-layered structure.

In one exemplary embodiment, the bank layer 164 can be a non-black bank layer when the first electrode 210 comprises the reflective electrode layer 214. In one exemplary embodiment, the bank layer 164 can be a white bank layer consisting of a white heat dissipating material. Alternatively, the bank layer 164 can be a gray bank layer comprising the white heat dissipating material and the light-shielding material. It is possible to minimize or prevent the occurrence of dead pixels in the pixel region P and to improve image quality by introducing the non-black bank layer 164. In addition, it is possible to improve processing performances and credibility by applying the non-black bank layer 164.

In another exemplary embodiment, the first electrode 210 consists of at least one transparent conductive layer 212 and/or 216 without the reflective electrode layer 214. In this case, the bank layer 164 can be a black bank layer comprising the light-shielding material. In this case, it is possible to prevent or reduce regular reflection and diffuse reflection from metal electrodes and metal lines such as source and drain electrodes 152 and 154, and to improve reflection visibility and light scatting properties. In addition, it is possible to block efficiently light leakage from the metal lines or adjacent pixel regions, and thereby, improving image quality by introducing the black bank layer comprising the light-shielding material. In addition, it is possible to block efficiently light leakage from the metal lines or adjacent pixel regions, and thereby, improving image quality by introducing the black bank layer comprising the light-shielding material.

It will be apparent to those skilled in the art that various modifications and variations can be made in the light emitting display device and the light emitting display panel of the present disclosure without departing from the technical idea or scope of the disclosure. Thus, it is intended that the present disclosure cover the modifications and variations of the present disclosure provided they come within the scope of the appended claims and their equivalents.

What is claimed is:

1. A light emitting display device, comprising:
a substrate defining an emitting area and a non-emitting area surrounding the emitting area;
a thin film transistor disposed in the non-emitting area on the substrate;
a light emitting diode including a first electrode connected to a drain electrode of the thin film transistor and disposing in the emitting area;
a bank layer surrounding the first electrode at each pixel region and disposed in the non-emitting area; and
a column spacer disposed on the bank layer, the column spacer including a first column spacer and a second column spacer disposed sequentially on the bank layer,
wherein the first column spacer has a different shape from the second column spacer, and
wherein the at least one of the first column spacer and the second column spacer comprises a light-shielding material.

2. The light emitting display device of claim 1, wherein one of the first column spacer and the second column spacer has a cross-sectional shape of which width gradually increases toward the bank layer, and the other of the first column spacer and the second column spacer has a cross-sectional shape of which width gradually decreases toward the bank layer.

3. The light emitting display device of claim 1, wherein the first column spacer has a cross-sectional shape of which width gradually increases toward the bank layer and the second column spacer has a cross-sectional shape of which width gradually decreases toward the bank layer.

4. The light emitting display device of claim 1, wherein both the first column spacer and the second column spacer have the light-shielding material.

5. The light emitting display device of claim 1, wherein the light-shielding material is selected from a black colorant of one of a black pigment and a black dye, carbon black, a carbon nanotube, graphene, and combinations thereof.

6. The light emitting display device of claim 1, wherein the light emitting display device further comprises a passivation layer covering the thin film transistor, and wherein the passivation layer comprises a light-shielding material.

7. The light emitting display device of claim 1, wherein the bank layer comprises a white bank layer or a gray bank layer.

8. The light emitting display device of claim 7, wherein the white bank layer comprises white heat dissipating particles, and the gray bank layer comprises white heat dissipating particles and a light-shielding material.

9. The light emitting display device of claim 8, wherein weight ratio between the white heat dissipating particles and the light-shielding material is 2:8 to 8:2.

10. The light emitting display device of claim 1, wherein the bank layer comprises heat dissipating particles.

11. The light emitting display device of claim 10, wherein the heat dissipating particles comprises white heat dissipating particles.

12. The light emitting display device of claim 10, wherein the heat dissipating particles comprises boron nitride BN.

13. The light emitting display device of claim 10, wherein the heat dissipating particles are selected from a metal material, a carbon-containing material, an inorganic oxide, an inorganic nitride, an inorganic arsenide, an inorganic carbide, and combinations thereof.

14. The light emitting display device of claim 13, wherein the metal material is selected from aluminum Al, gold Au, copper Cu, silver Ag, and combinations thereof.

15. The light emitting display device of claim 13, wherein the carbon-containing material is selected from graphite, graphene, a carbon nanotube CNT, and combinations thereof.

16. The light emitting display device of claim 13, wherein the inorganic oxide is selected from aluminum oxide Al₂O₃, silica SiO₂, magnesium oxide MgO, zinc oxide ZnO, zirconium oxide ZrO₂, and combinations thereof.

17. The light emitting display device of claim 13, wherein the inorganic nitride is selected from aluminum nitride AlN, boron nitride BN, and combinations thereof.

18. The light emitting display device of claim 13, wherein the inorganic arsenide is boron arsenide BAs.

19. The light emitting display device of claim 1, wherein the first electrode comprises:
a reflective electrode layer; and
a transparent conductive layer disposed on a top surface of the reflective electrode layer or a bottom surface of the reflective electrode layer.

20. The light emitting display device of claim 19, wherein the bank layer comprises a white bank layer or a gray bank layer.
